(19) United States
(12) Patent Application Publication
(10) Pub. No.: US 2016/0138160 A1
(43) Pub. Date: May 19, 2016

(54) REACTIVE ULTRAVIOLET THERMAL PROCESSING OF LOW DIELECTRIC CONSTANT MATERIALS

(71) Applicant: Lam Research Corporation, Fremont, CA (US)

(72) Inventors: Darcy E. Lambert, Hayward, CA (US); Casey Holder, Tualatin, OR (US); George Andrew Antonelli, Portland, OR (US)

(21) Appl. No.: 14/546,990

(22) Filed: Nov. 18, 2014

(51) Int. Cl. C23C 16/48; C23C 16/52; C23C 16/458; C23C 16/455; C23C 16/40

(52) U.S. Cl. CPC C23C 16/48; C23C 16/455; C23C 16/40; C23C 16/458; C23C 16/52

(57) ABSTRACT

Various embodiments herein relate to methods and apparatus for preparing a low-k dielectric material on a semiconductor substrate. The dielectric material may include porogens distributed throughout a structural matrix. A reactive ultraviolet thermal processing operation is performed to promote removal of the porogens from the dielectric material. By flowing a weak oxidizer such as carbon dioxide into the reaction chamber during UV exposure, the rate at which the porogens are removed can be enhanced in a controllable manner.

### BACKGROUND

Many different types of materials are used to fabricate semiconductor devices. One type of material commonly used is low dielectric constant (low-k) material. Low-k materials are often used as inter-metal and/or inter-layer dielectrics between conductive interconnects. The low-k materials reduce the delay in signal propagation due to capacitive effects. A dielectric material having a low dielectric constant will also have a low capacitance, and a resulting RC delay of an integrated circuit constructed with such a material will be lower as well.

In one method of preparing low-k materials, a dielectric film having a number of removable porogens scattered throughout a structural matrix is deposited on a substrate. The film is then exposed to thermal energy and/or ultraviolet radiation to promote removal of the porogens and cross-linking of the matrix to harden the film. Removal of the porogens results in the formation of pores within the matrix, thereby lowering the dielectric constant of the film.

### SUMMARY

Certain embodiments herein relate to methods and apparatus for performing reactive UV thermal processing of low dielectric constant materials. In various embodiments, carbon dioxide or another weak oxidizer is provided to a reaction chamber during a UV curing operation. The film being cured may be a low-k material including porogens distributed throughout a structural matrix. One purpose of the curing operation is to remove the porogens from the matrix, thereby decreasing the dielectric constant of the film. The presence of carbon dioxide or other weak oxidizers can help promote rapid but controllable removal of porogens. Compared to strong oxidizers such as molecular oxygen (O₂) or ozone (O₃), weak oxidizers are substantially more feasible for use with reactive UV thermal processing of low-k dielectric materials. The low rate of photodissociation of carbon dioxide is one factor that differentiates processes using carbon dioxide and other weak oxidizers from infeasible/uncontrollable processes employing oxygen or other strong oxidizers.

In one aspect of the disclosed embodiments, a method of preparing a film on a substrate is provided. The method may include receiving the substrate in a processing chamber, the substrate having the film thereon, where the film includes a carbon-containing dielectric film including porogens and a structure former, the film having a first dielectric constant; flowing a processing gas into the reaction chamber and exposing the substrate to the flow of processing gas, where the processing gas includes carbon dioxide and an inert carrier gas; exposing the substrate and the processing gas to ultraviolet (UV) radiation, where the UV radiation includes wavelengths that result in photodissociation of a portion of the carbon dioxide in the processing gas to thereby form carbon monoxide and oxygen radicals; and reacting the film on the substrate with the oxygen radicals to thereby remove the porogens from the film, thereby reducing the dielectric constant of the film to a second dielectric constant.

The UV radiation may include wavelengths between about 185-230 nm in various embodiments. For example, in some cases the UV radiation includes wavelengths between about 190-210 nm, or between about 190-200 nm. The carbon dioxide may be provided to the reaction chamber at a partial pressure between about 0.1-10 T. In some cases the partial pressure of the carbon dioxide is between about 1-2 T. The processing gas may include between about 5-30% carbon dioxide, as measured by volumetric flow rates. In some cases, the processing gas includes between about 10-25% carbon dioxide, as measured by volumetric flow rates. In various embodiments, the processing gas does not include strong oxidizers. For instance, in a number of embodiments the processing gas does not include molecular oxygen (O₂). Further species that may be excluded from the processing gas may include nitrogen dioxide (NO₂), nitric oxide (NO), ozone (O₃), and hydrogen peroxide (H₂O₂).

As stated, the method lowers the dielectric constant of the film. In some embodiments, the second dielectric constant is between about 2.2-2.25. In certain embodiments, exposing the substrate and the processing gas to UV radiation may include performing a staged curing operation, where UV conditions exposed to the substrate during a first stage are different from UV conditions exposed to the substrate during a second stage. In certain cases, the reaction chamber includes multiple stations for simultaneously processing multiple substrates. The different stages of the staged curing operation may take place in different stations in the reaction chamber. In other cases, the two or more stages may occur in one station. In some embodiments, the reaction chamber includes at least a first UV radiation source and a second UV radiation source, the first UV radiation source providing UV radiation to a first station and the second UV radiation source providing UV radiation to a second station, the method further including modulating at least one of the first and second UV radiation sources to independently modulate the photodissociation of carbon dioxide in the first and second stations. Modulating at least one of the first and second UV radiation sources may include, for example, changing a range of wavelengths exposed to the substrate from at least one of the first and second UV radiation sources. In some implementations, the reaction chamber includes at least a first UV radiation source for providing UV radiation to a first station and a second UV radiation source for providing UV radiation to a second station, where the first UV radiation source exposes the substrate to radiation at wavelengths that photodissociate carbon dioxide, and where the second UV radiation source exposes the substrate to radiation at wavelengths that do not substantially photodissociate carbon dioxide.

The method may be performed on relatively thin films. For example, in some embodiments the film has a thickness of about 200 nm or less. The photodissociation of carbon dioxide may preferentially occur in certain parts of the reaction chamber. For instance, the photodissociation of carbon dioxide preferentially occurs proximate the substrate as compared to locations in the reaction chamber removed from the substrate in some cases. The preferential dissociation may occur as a result of a temperature differential within the reaction chamber. In some cases during exposing the substrate and processing gas to UV radiation, there is a temperature differential of at least about 150° C. between the substrate and a window through which the UV radiation passes before reaching the substrate.

In another aspect of the disclosed embodiments, a method is provided, including: receiving a substrate in a processing chamber, the substrate having a film thereon, where the film includes porogens and a structure former; and exposing the substrate to a processing gas while exposing the substrate to ultraviolet (UV) radiation to thereby remove the porogen, where the processing gas includes an inert carrier gas and between about 5-30% carbon dioxide, as measured by volumetric flow rate.

In certain embodiments, the UV radiation includes wavelengths between about 185-230 nm, for example between about 190-210 nm, or between about 190-200 nm. Further, the processing gas may be substantially free of molecular oxygen.

In a further aspect of the disclosed embodiments, an apparatus for preparing low-k dielectric films is provided, the apparatus including: a reaction chamber; a substrate support for supporting a substrate in the reaction chamber; an ultraviolet (UV) radiation source configured to deliver UV radiation to the substrate on the substrate support; an inlet for providing processing gas to the reaction chamber and an outlet for removing material from the reaction chamber; and a controller including instructions for exposing the substrate to the processing gas while exposing the substrate to UV radiation from the UV radiation source to thereby remove porogens from an exposed film on the substrate, where the processing gas includes an inert carrier gas and between about 5-30% carbon dioxide, as measured by volumetric flow rate.

These and other features will be described below with reference to the associated drawings.

### BRIEF DESCRIPTION OF THE DRAWINGS

FIG. 1 shows data related to film shrinkage vs. flow of reactant gas during reactive UV thermal processing operations using oxygen or carbon dioxide as a reactant gas.

FIG. 2A illustrates a trend line related to the absorption cross section of carbon dioxide.

FIG. 2B illustrates a trend line related to the absorption cross section of ozone.

FIG. 3 illustrates trend lines related to the absorption cross section of carbon dioxide at different temperatures.

FIG. 4 shows data related to the dielectric constant of films prepared using certain disclosed reactive UV thermal processing operations.

FIG. 5 depicts a flow chart illustrating a method of preparing a low-k film using reactive UV thermal processing according to certain embodiments.

FIG. 6 illustrates a reaction chamber according to certain disclosed embodiments.

FIGS. 7A and 7B depict a multi-station reaction chamber according to certain disclosed embodiments.

### DETAILED DESCRIPTION

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards, magnetic recording media, magnetic recording sensors, mirrors, optical elements, micro-mechanical devices and the like.

In the following description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### I. Reactive Ultraviolet Thermal Processing

In general terms, various embodiments herein relate to methods and apparatus for forming low-k dielectric materials using reactive ultraviolet thermal processing. In these processes, dielectric films are exposed to ultraviolet radiation in the presence of a reactant, often while the substrate is positioned on a heated pedestal. In various embodiments, the reactant is a weak oxidizer. Examples of weak oxidizers include carbon dioxide (CO₂), water (H₂O), methanol (CH₃OH), ethanol (C₂H₅OH), isopropyl alcohol (C₃H₇OH), other oxygen-containing hydrocarbons (CₓH_{y}O_{z}), and combinations thereof. In a particular example, the reactant includes carbon dioxide. Although many of the forgoing embodiments are presented in the context of a carbon dioxide reactant, it is contemplated that other weak oxidizers may also be used. In various embodiments, the reactant may be free or substantially free of molecular oxygen (O₂) (as used herein, a reactant/processing gas that is “substantially free” of a species means that the reactant may contain only trace amounts of the species in question). The reactant may also be substantially free of other strong oxidizers including, but not limited to, nitrogen dioxide (NO₂), nitric oxide (NO), ozone (O₃), hydrogen peroxide (H₂O₂), and combinations thereof.

The weak oxidizer may be delivered in gaseous form. If the reactant is liquid at relevant processing temperatures, a liquid delivery system may be provided. In certain embodiments a liquid reactant may be vaporized or otherwise atomized for delivery to a reaction chamber.

The presence of the weak oxidizer results in an increased rate of porogen removal, and a corresponding increased reaction/curing rate. This increased reaction rate results in higher throughput. However, in certain applications, introduction of an oxidizing species (especially a strongly oxidizing species) into a reaction chamber will cause an unacceptable increase in dielectric constant due to excessive removal of carbon from the film. Thus, these considerations are balanced against one another when considering whether and which oxidizers to introduce. It has been found that the presence of carbon dioxide (and other weak oxidizers) can promote increased reaction rate and increased throughput while still fabricating high quality, low dielectric constant films and devices.

### A. Porogen Removal

Methods described herein involve forming a low-k dielectric material by way of a dielectric precursor layer that contains both a porogen and a dielectric matrix formed in regions around the porogen. The porogen is removed from the precursor layer to create a low-k dielectric layer. Within the precursor layer, the porogen resides in locations that will subsequently become void locations in the final dielectric layer. Hence, the porogen and dielectric matrix typically exist as separate phases within the precursor layer. To some degree, the porogen defines the porosity, void volume, tortuosity and other parameters characterizing the pore morphology in the final low-k dielectric material. In some cases, the pore morphology is set before the porogen is removed. In other cases, it is set during the porogen removal process. Further, the dielectric matrix may assume its final composition and structure either before or during the porogen removal process. In alternative methods, the structure former and porogen are deposited separately in a two-phase process. For example, in some mesoporous films, a template-forming precursor, solvent and catalyst are mixed and applied by spin-coat or print-on methods to form a template in a first process phase, then a silica-forming precursor is introduced to the formed template in a second process step such as supercritical infusion into a polymer matrix. Depending on the application, the thickness of the precursor film may range between about 10 nanometers and 3 micrometers in some examples.

Generally, a porogen is any removable material that defines void regions in a dielectric matrix. This does not include small organic end groups on a structure former backbone that can be, though often are preferably not, removed from the precursor film.

In the case of an ordered porous or mesoporous dielectric matrix, the porogen is frequently referred to as a “template.” In many cases, the porogen is or includes an organic material.

In some cases the porogen is randomly distributed throughout the precursor film and other cases it is ordered in a repeating structure throughout the film. One type of ordered porogen, for example, is a block copolymer that has chemically distinct components (e.g., polyethylene oxide (PEO) and polypropylene oxide (PPO)) that segregate into separate phases. The discussion herein will refer to porogen and porogen materials in general and are intended to include any type of porogen, ordered or non-ordered, organic or inorganic, unless otherwise specified.

Frequently, the porogen is a hydrocarbon. The following is a non-comprehensive list of precursor films (listed by type of porogen molecules) that may be suitable. “Low temperature porogens” are deposited below about 200° C. and “high temperature porogens” are deposited above about 200° C.

One class of porogens is polyfunctional cyclic non-aromatic compounds, such as alpha-terpinenes (ATRPs). Suitable alpha-terpinene derivatives include, for example, alpha-terpinene itself, substituted alpha-terpinenes, and multi-ring compounds containing the alpha-terpinene nucleus. Other compounds include functional groups such as —CH═CH₂, —CH═CH—, —C≡CH, —C≡C—, —C≡O, —OCH₃. An example of one of these compounds is 1,2,3,4-tetramethyl-1,3-cyclopentadiene (TMCP) (C₉H₁₄). Three-dimensional multi-ring compounds such as 5-ethylidene-2-norbornene (ENB) are also suitable. Another ATRP compound that can be used is D-limonene.

In some cases, the porogen and structure former reside in the same compound. That is, the porogen is a removable moiety in a compound that contains moieties serving as structure formers covalently bonded to moieties serving as the porogen. Nominally, the porogen moiety is a large bulky organic substituent that will leave pores in the resulting dielectric film. Examples of such species are organic silanes such as di-tert-butylsilane, phenyldimethylsilane, and alkoxysilanes such as 5-(bicycloheptenyl)methyldimethoxysilane (BMDS) and 5-(bicycloheptenyl)triethoxysilane (BTS) (SiCl₃O₃H₂₄). These compounds may be deposited using CVD or spin on methods, for example.

As indicated, the structure former serves as a backbone for the resulting porous low-k film. Many different chemical compositions may be used as the structure former. In some embodiments, the composition includes silicon and oxygen. Sometimes it also includes carbon and/or other elements and even metals. For relatively thick precursor layers, it will sometimes be desirable to use structure formers that are not opaque to the UV radiation.

Examples of precursors for structure formers include silanes, alkylsilanes (e.g., trimethylsilane and tetramethylsilane), alkoxysilanes (e.g., methyltriethoxysilane (MTEOS), methyltrimethoxysilane (MTMOS) diethoxymethylsilane (DEMS), methyldimethoxysilane (MDMOS), methyldiethoxy silane (MDEOS), trimethylmethoxysilane (TMMOS) and dimethyldimethoxysilane (DMDMOS)), linear siloxanes and cyclic siloxanes (e.g. diethylmethylsiloxane (DEMS), octamethylcyclotetrasiloxane (OMCTS), tetramethylcyclotetrasiloxane (TMCTS)). Note that one example of a silane is di-tert-butylsilane, described above.

The thickness of the precursor film (and hence the resulting dielectric layer) depends upon the ultimate application. For an interlayer dielectric or packaging application, the thickness may range from 100 angstroms up to about 2 to 3 microns. In some cases, extra thickness provides some amount of sacrificial dielectric to accommodate a subsequent planarization step. Thinner precursor films may be increasingly used with increasingly smaller technology nodes. For example, many of the processes described herein may be advantageously used with thin films of less than about 200 nm, or less than about 150 nm. In some such cases the films may have a thickness of at least about 50 nm. Without being bound by theory or mechanism of action, it is believed that certain of the disclosed embodiments are particularly useful for films in this thickness range due to a diffusion-based nature of the reactive ultraviolet thermal process used to drive porogen removal. By contrast, where the disclosed methods are performed on thicker films, a diffusion-based process may not be able to fully penetrate the film, and the film may exhibit multi-layer effects.

The porosity of the dielectric film may be connected, and may include pores that are introduced by removal of a porogen from a dielectric matrix and/or pores that are inherent to the dielectric matrix. For example, a carbon doped oxide (CDO) matrix may have porosity due the incorporation of methyl or other organic groups that remain in the CDO matrix after porogen removal. The porous dielectric film may include mesoporosity and/or microporosity. Mesoporosity generally refers to pore sizes of 2 nm-50 nm and microporosity to pore sizes less than 2 nm. In dielectrics having connected porosity, the size of at least some of the connected pores may be on a continuum with micropores having sizes on the order of angstroms to nanometers, connected to mesopores having sizes on the order of nanometers to tens of nanometers.

As noted above, a precursor may include both a porogen and organic groups directly bonded to organic-silicon oxide matrix. In many cases, removal of former is desirable while removal of the latter is not. This is because non-removed, non-porogen organic end groups are introduced to intrinsically increase porosity. In some implementations, for example, microporosity may be incorporated into an ultra low-k (ULK) dielectric by organic end groups in a silicon oxide matrix and mesoporosity may be incorporated into a ULK dielectric by removal of a porogen.

Methods of porogen removal suffer from various drawbacks. Current cure technology for ULK thin films relies on the application of ultraviolet (UV) light and elevated temperature. The goal of this thermal UV process is to both remove the porogen to lower the effective dielectric constant of the thin film as well as cross-link the matrix of the ULK thin film to increase its mechanical properties. However, as the application of UV light both removes porogen and cross-links the silicon-organic matrix simultaneously, there is a limitation on the obtainable final properties of the cured film. Excessive cross-linking can lead not only to an increase in the dielectric constant but also to the trapping of porogen inside the ULK thin film leading to increased electrical leakage and degraded time-dependent-dielectric-breakdown (TDDB) at end of line integration. Further, various methods including plasma exposure are susceptible to damaging the dielectric material by removing too many organic groups on the backbone of the silicon-organic matrix. As such, an improved method of removing porogens in dielectric film is desired.

### B. Use of Reactants During Ultraviolet Processing

Most ultraviolet-based porogen removal processes are performed in reaction chambers having inert atmospheres (e.g., helium, argon, nitrogen, etc.). The purpose of the inert gas is to promote heat transfer within the chamber. The inert gas does not participate in any chemical reactions. However, certain ultraviolet thermal processes may benefit from being performed in a reactive atmosphere. Previous methods have explored the use of photo-active oxidizers such as oxygen (O₂) and/or reducing agents such as ammonia (NH₃) in certain ultraviolet thermal processes. However, these reactive processes, when used in the context of forming low-k materials, have proven too aggressive and too difficult to control, leading to excessive reaction rates and significant loss of organic groups from the low-k matrix. The substantial loss of organic groups in the matrix results in a dramatic and unacceptable increase in the dielectric constant of the treated material.

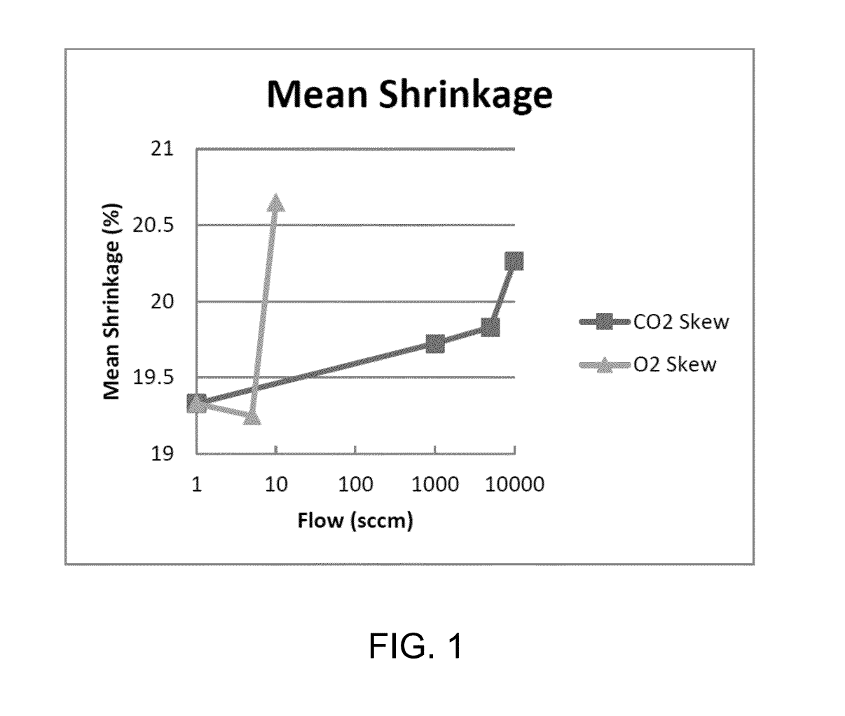

FIG. 1 presents a graph of certain experimental results that show the mean shrinkage of a film during a UV thermal cure where two different reactants are used. The shrinkage is a result of the curing process and occurs over a set time period for each case, therefore providing information about the rate at which the film is cured. Larger shrinkage values relate to faster curing processes. In one case oxygen is flowed into the reaction chamber, and in the other case carbon dioxide is flowed into the reaction chamber. In both cases the reactant is provided in an inert carrier gas. The reactants are introduced while the substrate is exposed to ultraviolet radiation in the reaction chamber. When oxygen is introduced into the reaction chamber, even very small flows (e.g., 10 sccm O₂ in a total flow of 45,000 sccm) result in substantial increases in shrinkage. This means that the presence of even very low amounts of molecular oxygen in the chamber significantly increases the curing rate (i.e., the rate at which carbon/porogen is removed from the film).

This extremely high degree of sensitivity in the curing rate is undesirable. In order to maintain the curing rate at an effective level that allows for porogen removal and cross-linking without removing excessive amounts of carbon, the amount of molecular oxygen should be maintained at a very low level (e.g., below about 0.05% of a total flow, as measured in sccm, on the order of ppm O₂ in some cases). In other words, there should be several orders of magnitude difference between the flow rate of oxygen and the total flow rate. This large flow differential presents various practical problems. For instance, due to mixing limitations, it is difficult to achieve a uniform concentration of oxygen within the reaction chamber when the concentration of oxygen is so low. Further, it is difficult to maintain uniformity between process batches because even very small differences in oxygen concentration/partial pressure can result in huge differences in the curing rate. The differences in curing rate can lead to significant differences in film properties between substrates processed in different batches.

Without wishing to be bound by theory or mechanism of action, it is believed that the high reactivity of oxygen in the context of ultraviolet thermal processing of low-k dielectric materials relates to the formation of ozone. When molecular oxygen is exposed to ultraviolet radiation, a portion of the oxygen molecules (O₂) are split into individual oxygen atoms (i.e., atomic oxygen radicals, O*). The atomic oxygen then combines with another oxygen molecule (O₂) to form an ozone molecule (O₃). Ozone molecules are very reactive, and act to remove both porogens and organic groups directly bonded to the organic silicon oxide matrix.

Returning to FIG. 1, the mean shrinkage (and therefore reaction/curing rate) is much more stable where carbon dioxide is used as the reactant (the carbon dioxide being delivered along with an inert carrier gas). Notably, the x-axis on FIG. 1 is logarithmic. Thus, FIG. 1 shows that the shrinkage and reaction rate are very sensitive to the concentration of oxygen, and that introduction of even 10 sccm O₂ results in significant shrinkage, and therefore an uncontrollably high reaction rate. By contrast, while films treated under a carbon dioxide atmosphere show increased shrinkage and reaction rate compared to the case where no carbon dioxide is used (e.g., the data points on the y-axis), this increase is seen over a much wider range of flow rates, including flow rates that are sufficiently high to promote good mixing within a batch, and good uniformity between batches. In other words, the presence of carbon dioxide in the UV exposure chamber is beneficial in increasing reaction rates (i.e., increasing throughput), and compared to the reaction rate benefit realized from the presence of molecular oxygen, the benefit can be implemented in a much more controllable, stable, repeatable manner.

When carbon dioxide is exposed to certain wavelengths of ultraviolet radiation, a portion of the carbon dioxide molecules may be photodissociated carbon monoxide molecules (CO) and atomic oxygen radicals (O*).

CO₂+photon→CO+O*

The carbon monoxide molecule is very stable and is generally not broken down any further. Photodissociation of carbon monoxide occurs at very high energy/low wavelengths (e.g., at about 100 nm or less). According to various embodiments, ultraviolet radiation sources used in the ultraviolet thermal processing methods disclosed herein either do not emit significant amounts of radiation at this level, or have such radiation filtered out before reaching the substrate. Thus, the carbon monoxide is expected to remain stable. The atomic oxygen radical, however, is much more reactive. Atomic oxygen radicals generated by photodissociation of carbon dioxide may interact with the film directly to oxidize the matrix (e.g., by removing carbon from the matrix). Oxidation of the matrix may result in forming dangling silicon bonds, which may in turn react with a further oxygen radical or a silanol group (Si—OH). A UV-driven condensation reaction may then take place to cross-link the matrix. The wavelength of a photon used in such a reaction may be less than about 300 nm. The cross-linking reaction may occur as follows:

Si—OH+Si—OH+photon→Si—O—Si+H₂O

Additionally, atomic oxygen may react with other atomic oxygen to form low amounts of molecular oxygen. Atomic oxygen may also react with such molecular oxygen to form ozone. However, such ozone formation is likely to occur at extremely small levels, if at all, due to the relatively low dissociation rate of carbon dioxide and the resultant low rate of formation of atomic and molecular oxygen. Further, any ozone formed is likely to be photodissociated back into molecular and atomic oxygen due to the presence of the UV radiation.

Without being bound by a particular theory, it is believed that one of the reasons carbon dioxide (and other weak oxidizers) may be used to controllably and repeatably increase reaction rates is that only a small percentage of the carbon dioxide is photodissociated upon exposure to UV radiation. The low rate of photodissociation may be promoted by using an apparatus where a relatively low amount of UV radiation of relevant wavelengths reaches the gas in the reaction chamber. The relatively low amount of UV radiation may be achieved by using a radiation source that outputs relatively little radiation at relevant wavelengths, and/or by using a filter to control the amount of radiation at relevant wavelengths. Depending on temperature, carbon dioxide absorbs UV radiation having wavelengths on the order of about 200 nm.

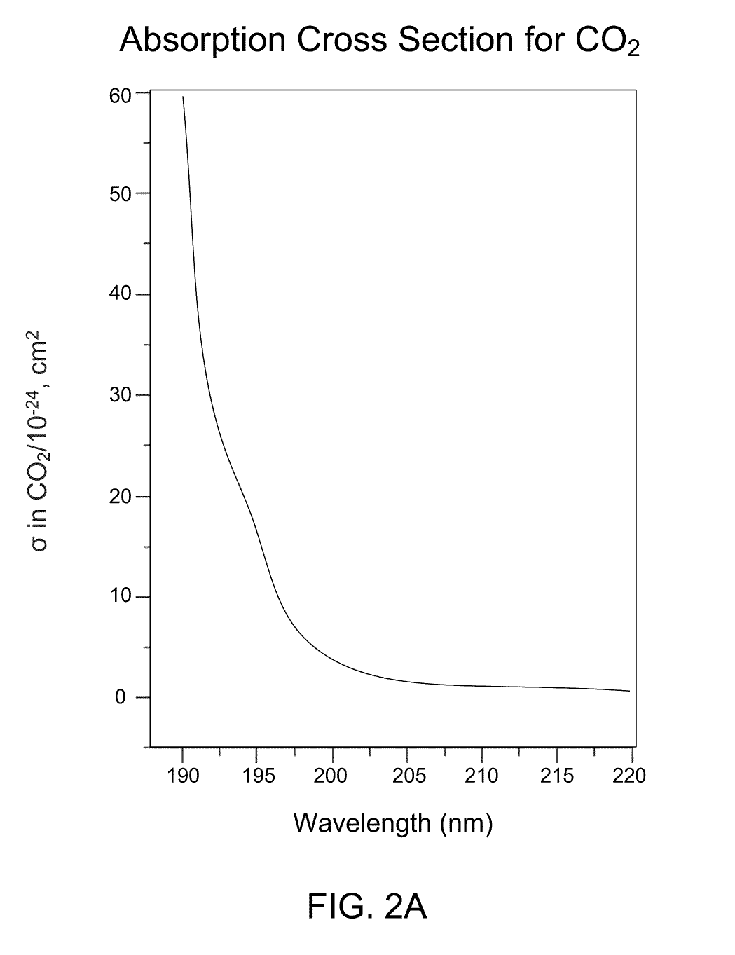

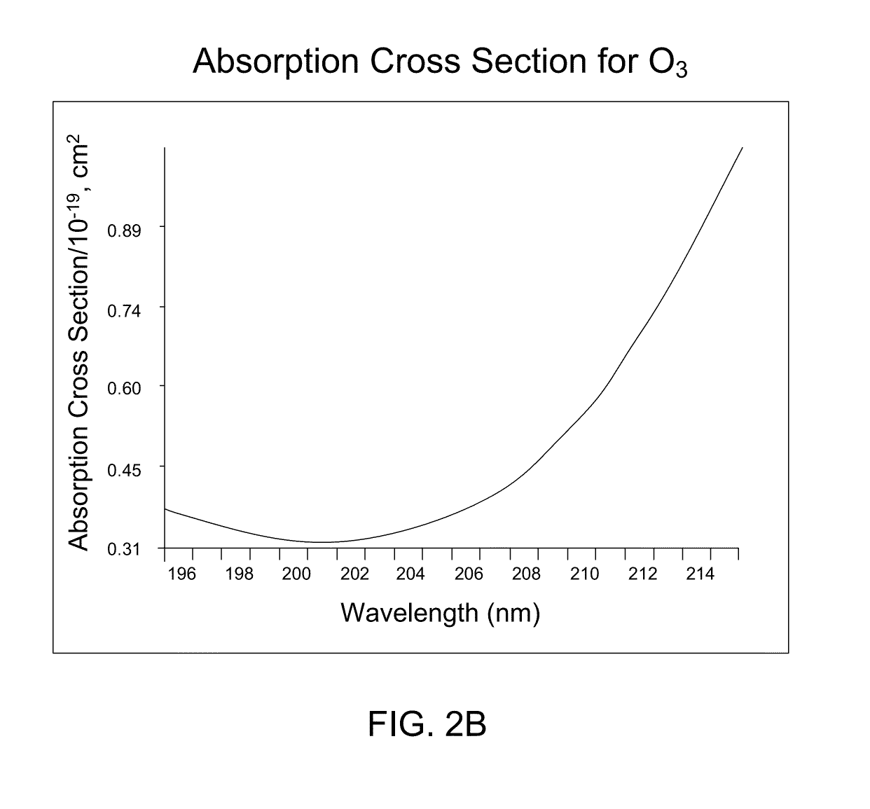

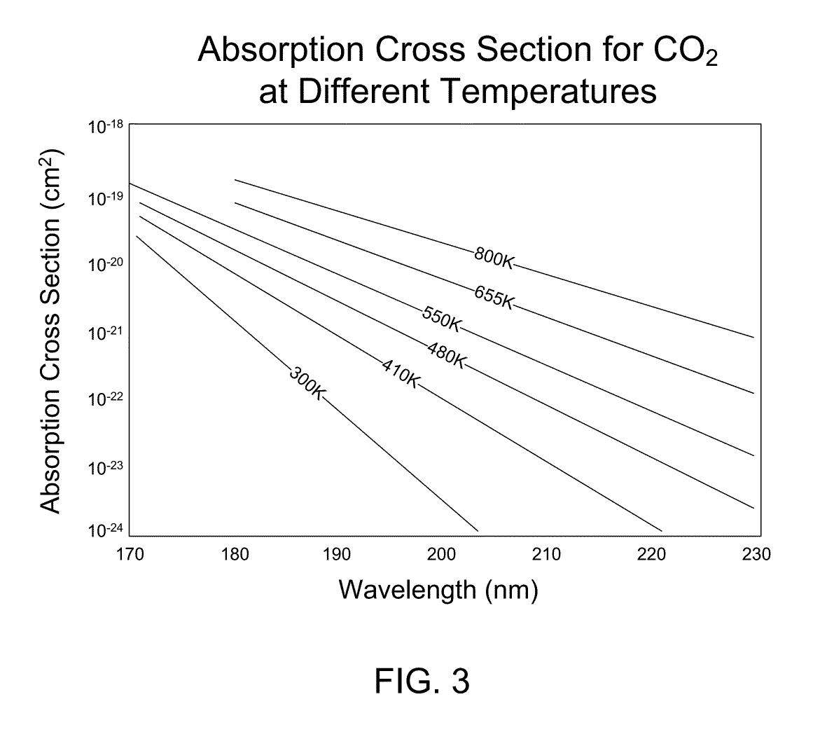

FIG. 2A presents a trend line illustrating the absorption onset in carbon dioxide observed by various researchers in the range of about 190-220 nm. This trend line is generated based on data presented in “Deep-UV absorption and Rayleigh scattering of carbon dioxide,” D. Ityaksov, et al., Chemical Physical Letters, 462, 31-34 (2008). FIG. 2B presents a trend line illustrating the absorption cross section of ozone in the range of about 195-215 nm. This trend line is generated based on data presented in “Ozone UV Spectroscopy. II. Absorption cross-sections and temperature dependence,” J. Malicet, et al., Journal of Atmopheric Chemistry, 21, 263-273 (1995). FIG. 3 presents trend lines illustrating the absorption cross section of carbon dioxide at various temperatures. These trend lines are generated based on data presented in “High-temperature measurements of VUV-absorption cross sections of CO2 and their application to exoplanets,” O. Venot, et al., Astronomy & Astrophysics, 551, A131 (2013). FIG. 3 shows that the absorption of UV radiation in CO₂ is strongly temperature dependent. Generally, the greater the absorption cross section, the easier it is to photoexcite (and photodissociate) the molecule.

Together, FIGS. 2A and 3 show that depending on the temperature, carbon dioxide absorbs UV radiation having wavelengths in the range of about 230 nm or less, for example about 220 nm or less, about 210 nm or less, or about 200 nm or less. As such, a UV radiation source for performing the disclosed embodiments may emit radiation including the stated wavelengths. In these or other cases, the UV radiation source may emit wavelengths greater than about 180 nm, for example greater than about 185 nm, or greater than about 190 nm. FIGS. 2A and 3 also suggest (based on the low values on the y-axes) that the likelihood of photodissociating a particular carbon dioxide molecule, even where proper wavelengths of radiation are provided, is relatively low. In other words, the proportion of carbon dioxide molecules that photodissociate is quite low. This low rate of photodissociation helps ensure that the concentration of atomic oxygen within the reaction chamber remains low. The low concentration of atomic oxygen means that the rate of molecular oxygen formation is also low, and that the rate of ozone formation is extremely low or non-existent. As such, the atomic oxygen is present in the reaction chamber at relatively low (but reproducible and uniformly mixable) amounts such that it can controllably oxidize the film matrix and help promote removal of porogens and controlled cross-linking.

By contrast, FIG. 2B provides the absorption cross section of ozone. There is a huge difference in absorption between carbon dioxide and ozone at/near these wavelengths. The ozone absorbs substantially more photons, and therefore dissociates at a substantially greater rate. For instance, for a given wavelength/UV source, the absorption cross section of carbon dioxide is about 5 orders of magnitude less than that of ozone. This suggests that if ozone were provided to the reaction chamber, it would photodissociate at a much greater rate than carbon dioxide (assuming exposure to the same UV conditions). As a gross estimate assuming normal operating conditions using a mercury lamp, the rate of photon absorption in carbon dioxide may be on the order of about 5E-7 photons/s, while the same conditions would produce a rate of photon absorption in ozone on the order of about 20 photons/s. These estimates are based on calculations involving the cross section for photodissociation and the mean intensity of radiation as a function of wavelength. These rates are very gross estimates, and the difference in these rates is more important than the actual values. The difference in rates suggests that ozone would dissociate much more quickly, to a much greater extent, than carbon dioxide. This rapid and extensive photodissociation would render the reactive UV process uncontrollable.

The absorption cross section for molecular oxygen (O₂) lies between that of carbon dioxide and ozone, and the absorption values are closer to those of ozone than those of carbon dioxide. Therefore, as described herein, oxygen provided to a reaction chamber photodissociates at a rate substantially higher than carbon dioxide under the same UV conditions.

In various embodiments, the UV radiation source is provided behind a transparent window in order to maintain cleanliness of the lamp. The window may act to filter out certain wavelengths, for example wavelengths below about 190 nm, or below about 185 nm, or below about 180 nm. There may be a roll-off for radiation near these wavelengths. One reason that those of ordinary skill in the art have avoided the use of carbon dioxide as a reactive atmosphere for UV thermal processing is that it was believed that the rate of photodissociation of carbon dioxide would be unacceptably low such that it would not result in any processing benefits. It was thought that the rate of photodissociation would be very low because (1) most UV radiation sources used in UV thermal processing of low-k dielectrics emit most of their radiation at lower energy, higher wavelengths, and emit only a low amount of photons at the relevant wavelengths (e.g., on the order of about 200 nm), and because (2) the window was thought to block much of the radiation at the relevant wavelengths. With regard to the first point, using a different UV radiation source that emits significant radiation at the relevant wavelengths is not trivial. The light sources and processes have been optimized to process particular materials and achieve particular results. As such, one of ordinary skill in the art would not have chosen to switch to a different UV radiation source that would emit at lower wavelengths, as this would involve significant process engineering to re-optimize the various processing conditions for the different materials. Further, use of a different UV radiation source may render certain materials used in current processes unsuitable. With regard to the second point, this belief was particularly relevant considering that at room temperature, the range of wavelengths that carbon dioxide absorbs significantly overlaps with the range of wavelengths that the window absorbs (i.e., it was thought that the window would absorb much or all of the relevant UV radiation before it could reach and photodissociate the carbon dioxide).

The temperature dependence of UV absorption illustrated in FIG. 3 may be exploited to have beneficial effects on the curing process in some embodiments. In UV thermal processes disclosed herein, a substrate may be placed on a heated pedestal and exposed to UV radiation while heated to an elevated temperature. The pedestal may be kept at a temperature between about 380-420° C. in some cases, for example at about 400° C. The UV radiation source may be provided above the substrate, behind a glass or other transparent window. The window may be at a significantly lower temperature than the substrate, for example at about 200° C. or less, with a temperature difference of at least about 150° C. compared to the substrate. Due to this temperature differential, the carbon dioxide may preferentially photodissociate proximate the substrate (where the temperature is elevated) compared to other portions of the reaction chamber (where the temperature is relatively lower). One result of this preferential photodissociation is that the atomic oxygen radicals are preferentially formed near the substrate, where they are wanted for removing porogens.

The presence of carbon dioxide in a reaction chamber used for UV treatment may have other benefits. For instance, the carbon dioxide may absorb (and therefore help filter out) high energy, low wavelength photons that may otherwise damage the film on the substrate. Because the carbon dioxide may be present in significant quantities, such filtering may be substantial. This filtering may help promote certain desirable film properties such as hardness. One possible explanation is that the high energy/low wavelength photons filtered out by the carbon dioxide would otherwise cause damage to the matrix by removing small carbon groups from the backbone of the matrix, which may deleteriously affect hardness. By contrast, the presence of oxygen in a reaction chamber does not have any similar filtering effect, at least in the context of processing low-k materials, because the oxygen is present at such low concentrations that the filtering cannot effectively take place.

The use of carbon dioxide (and/or other weak oxidizers) may affect certain other film properties, as well. It is important that any processing methods applied to low-k materials does not result in an unacceptable increase in the dielectric constant of the material. In the context of porogen removal, the dielectric constant can unacceptably rise where too much carbon is removed from the film, especially where the carbon is removed from organic groups directly bonded to organic silicon oxide matrix (as opposed to carbon present in a porogen). As such, there is a risk that when introducing oxidizing species into the curing atmosphere, the enhanced rate of carbon removal could remove too much carbon in an uncontrollable manner, thereby deleteriously increasing the dielectric constant of the film.

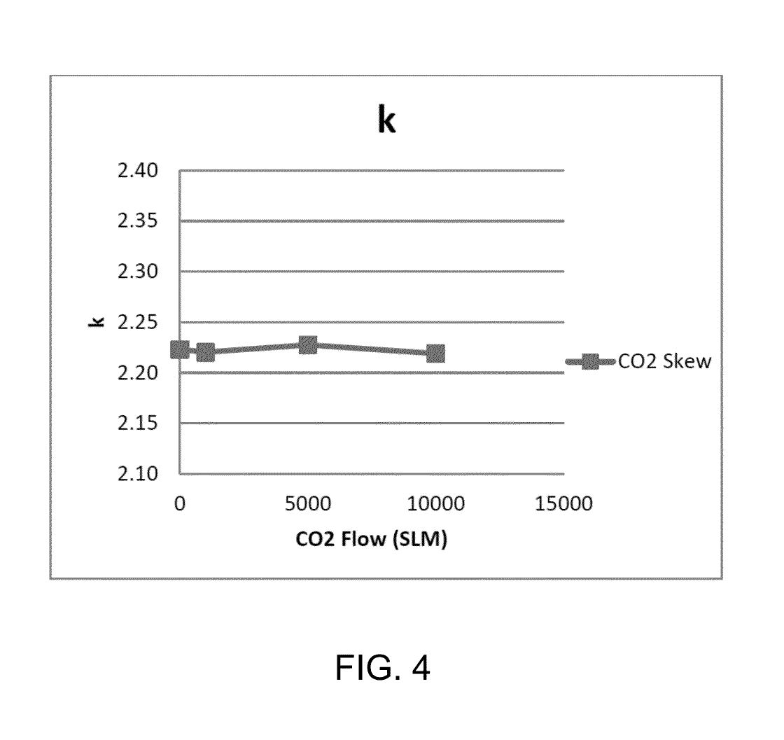

FIG. 4 presents data related to the dielectric constant of various low-k films exposed to UV radiation in the presence of carbon dioxide in an inert carrier gas. The different data points relate to substrates exposed to varying flow rates of carbon dioxide. The dielectric constant of the films remains relatively stable over a range of carbon dioxide flow rates. This suggests that the dielectric constant of the films is not overly sensitive to the amount of carbon dioxide present in the reaction chamber. In other words, carbon dioxide present at these levels does not result in unacceptably high removal of carbon in organic groups bonded to the organic silicon oxide matrix. The data in FIG. 4 was obtained using a total flow rate (carbon dioxide+inert carrier gas) of about 45,000 sccm, and a total pressure of about 10 Torr. Thus, the percentage of carbon dioxide in the gas, where present, was between about 1-25%, and the partial pressure of the carbon dioxide was between about 0.1-2.5 Torr.

In various embodiments, the percentage of carbon dioxide or other weak oxidizer in a process gas delivered to a UV thermal processing chamber (as measured by sccm) may be between about 1-30%, for example between about 5-30%, or between about 10-25%. In these or other cases, the percentage of carbon dioxide or other weak oxidizer present in the process gas may be at least about 1%, for example at least about 5%, at least about 10%, or at least about 20%. The percentage of carbon dioxide or other weak oxidizer present in the process gas may also be about 30% or less, for example about 25% or less, or about 20% or less. The optimal composition of the processing gas may depend on the material being processed, as well as the temperature and other processing conditions. In certain embodiments, the partial pressure of carbon dioxide in the processing chamber may be between about 0.1-10 Torr, for example between about 0.5-5 Torr, or between about 1-3 Torr, or between about 1-2 Torr. In these or other embodiments, the partial pressure of carbon dioxide in the processing chamber may be at least about 0.1 Torr, at least about 0.5 Torr, at least about 1 Torr, or at least about 2 Torr. The partial pressure of carbon dioxide present in the processing chamber may also be about 10 Torr or less, for example about 5 Torr or less, 3 Torr or less, or 2 Torr or less. The flow of carbon dioxide or other weak oxidizer may be between about 1-50 sccm per square centimeter of surface area of the substrate, for example between about 10-15 sccm per square centimeter of surface area of the substrate. As used herein, the surface area of the substrate is considered to be the area of a single face of the substrate. For instance, a 300 mm diameter wafer has a surface area of about 706 cm². As mentioned, the substrate may be maintained at an elevated temperature during exposure to UV radiation. In certain embodiments, the substrate is maintained at a temperature between about 380-420° C., though this is not intended to be limiting.

Other relevant processing conditions and considerations are further discussed in the following U.S. patents, each of which is herein incorporated by reference in its entirety: U.S. Pat. No. 8,465,991, titled “CARBON CONTAINING LOW-K DIELECTRIC CONSTANT RECOVERY USING UV TREATMENT,” U.S. Pat. No. 8,454,750, titled “MULTI-STATION SEQUENTIAL CURING OF DIELECTRIC FILMS,” and U.S. patent application Ser. No. 12/210,060, filed Sep. 12, 2008, and titled “PROGRESSIVE UV CURE.”

### C. Process Flow

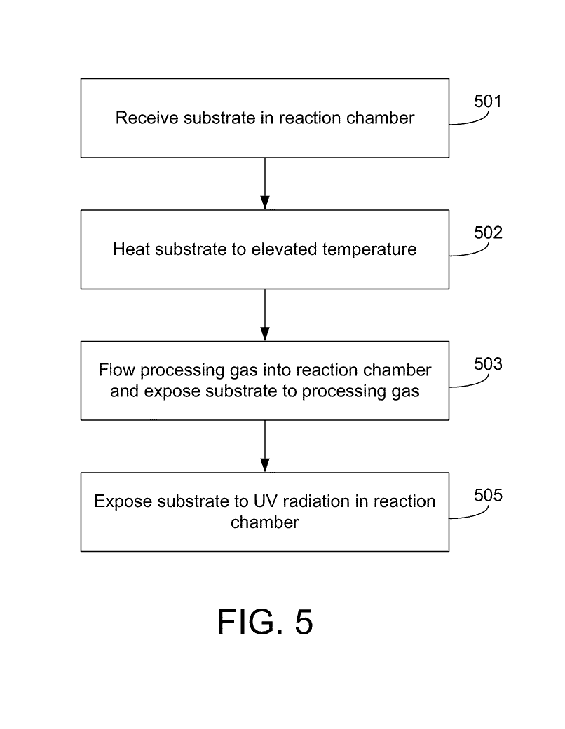

FIG. 5 presents a flow chart for a method of preparing a low-k film using reactive ultraviolet thermal processing according to certain embodiments. The method begins at operation 501, where a substrate is received in a reaction chamber. The substrate includes a layer of dielectric material having porogens distributed throughout a structural matrix as described herein. At operation 502 the substrate is heated (e.g., through a heated pedestal/substrate support), and at operation 503 the substrate is exposed to a flow of processing gas. The processing gas may include a weak oxidizer (e.g., carbon dioxide or another weak oxidizer) delivered in an inert carrier gas. At operation 505, the substrate is exposed to UV radiation. The UV radiation should include radiation at a wavelength or range of wavelengths that operate to photodissociate the weak oxidizer at the relevant temperature. However, the UV radiation may be optimized for removal of porogens, and the amount of radiation having a wavelength appropriate for photodissociation of carbon dioxide may be relatively small. For instance, the UV radiation may have an intensity peak at or near a wavelength that is optimal for removal of a particular porogen present in the dielectric film, while having a much smaller intensity of radiation at wavelengths that photodissociate carbon dioxide.

The degree of photodissociation is often small such that relatively few molecules of the weak oxidizer dissociate. The weak oxidizer dissociates into species that promote controlled removal of carbon from the dielectric material on the substrate. As a result of exposure to UV radiation in the presence of weak oxidizer, porogens are removed from the dielectric material on the substrate at a rapid but controllable rate. This rate is quicker than would otherwise be achieved using UV radiation in combination with an inert atmosphere. The UV radiation also promotes cross-linking within the material, as discussed herein.

Operations 502, 503, and 505 may overlap in time, and may occur in other orders. For example, in one embodiment operations 502, 503, and 505 begin at the same time, and optionally have the same duration. The heating operation 502, processing gas exposure operation 503 and the UV exposure operation 505 may have durations between about 10 seconds and 10 minutes.

In certain embodiments, the rate at which a dielectric film is treated is modulated during the treatment. Such modulation may occur through various means. In one implementation, the rate of treatment is modulated by varying the radiation source. For instance, the radiation may be turned on and off, or may switch between different wavelengths or sets of wavelengths. The radiation may modulate between (a) wavelengths that result in photodissociation of the weak oxidizer and (b) wavelengths that do not result in photodissociation of the weak oxidizer, or no radiation. The radiation during (a) may include, in certain embodiments, wavelengths between about 185-230 nm, or between about 190-210 nm, or between about 190-200 nm. The radiation during (b) may exclude, in certain embodiments, wavelengths in these same ranges. The radiation may also modulate between different intensities/power levels. In another implementation, the rate of treatment is modulated by varying the flow of weak oxidizer into the reaction chamber. In yet another implementation, the rate of treatment may be modulated by varying the temperature at which a substrate is maintained. Higher substrate temperatures increase the likelihood of photodissociation near the substrate, as indicated by the data in FIG. 3. These modulations may be done on an individual station-by-station basis in a multi-station apparatus. The UV radiation and substrate temperature are particularly easy to modulate at each station (each station being controlled independently) since each station is often equipped with its own UV radiation source and substrate support. Independent station-by-station control of the flow of processing gas may involve separating the chambers (e.g., through structures, gas curtains, etc.) from one another.

In some embodiments, the substrate may be exposed to UV radiation after the porogen is removed to increase cross-linking. If performed, the emission spectrum to which the substrate is exposed may be the same or different than that in block 505. Further, in some implementations, the substrate may or may not be exposed to carbon dioxide during the cross-linking operation. As discussed further below, even if the substrate is exposed to carbon dioxide during UV-mediated cross-linking, it may be at a temperature or UV wavelength at which significant photodissociation does not occur. The emission spectrum used for cross-linking may include wavelengths that are most efficient at the particular type of cross-linking used. As an example, a UV radiation source including spectral lines of less than about 250 nm may be used in some embodiments.

### II. Apparatus

The methods described herein may be performed by any suitable apparatus. A suitable apparatus includes hardware for accomplishing the process operations and a system controller having instructions for controlling process operations in accordance with the present invention. For example, in some embodiments, the hardware may include one or more process stations included in a process tool.

Examples of UV treatment apparatus are described in U.S. Pat. No. 8,137,465, issued Mar. 20, 2102 and incorporated by reference herein for all purposes. The plasma apparatus may be implemented in a loadlock attached to a UV treatment apparatus, for example, or attached to a common transfer module as the UV treatment apparatus.

Many different types of UV exposure apparatus may be employed. In some embodiments, the apparatus will include one or more chambers that house one or more substrates, with at least one chamber including a UV source. A single chamber may have one or more stations and may be employed for one, some or all operations. Each chamber may house one or more substrates for processing. For certain operations in which the substrate temperature is to be controlled, the apparatus may include a controlled temperature substrate support, which may be heated, cooled, or both. The support may also be controllable to provide defined substrate positions within a process module. The substrate support may rotate, vibrate, or otherwise agitate the substrate relative to the UV source.

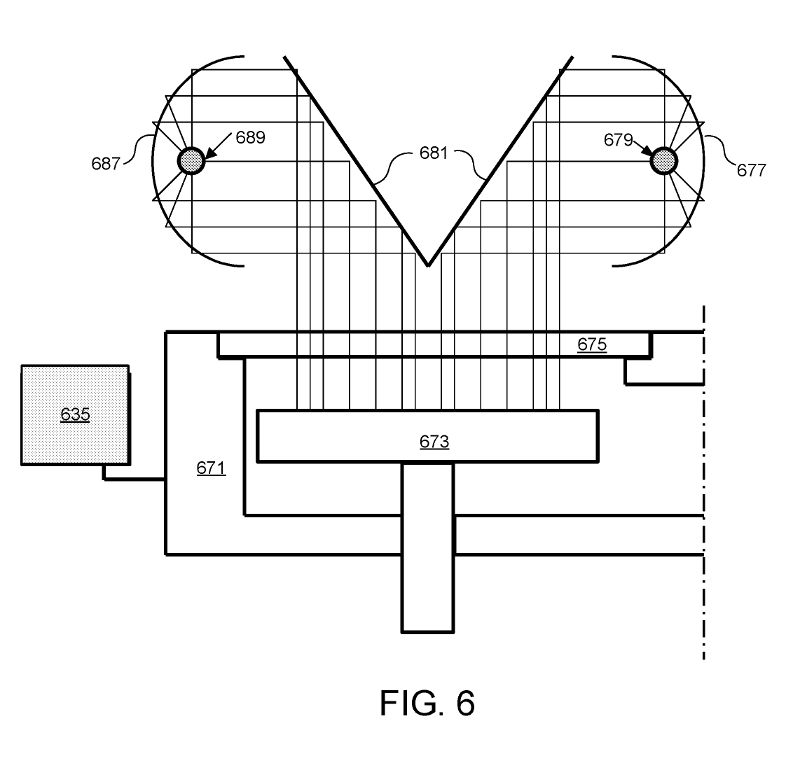

FIG. 6 depicts the arrangement of a UV light source suitable for implementations of certain methods described herein. In the example of FIG. 6, a cold mirror reflector diminishes the incidence of IR radiation on the substrate, while permitting UV radiation to be available for processing. For clarity, this figure depicts only one of the possible multiple processing stations available in an apparatus. Also, this figure omits depiction of the substrate for purposes of clarity, and shows a flood-type reflector. The principles depicted in FIG. 6 may also be applied to a focused reflector. Further, the UV apparatus may not include cold mirrors in certain embodiments.

Pedestal 673 is embedded into one station of a processing chamber 671. Window 675 is located appropriately above pedestal 673 to permit radiation of the substrate (not shown here) with UV output of the desired wavelengths from UV lamps 679 and 689. Suitable lamps for the UV light source may include, but are not limited to, mercury vapor or xenon lamps. Other suitable light sources include deuterium lamps, excimer lamps or lasers (e.g., excimer lasers and tunable variations of various lasers). Both lamps 679 and 689 are equipped with reflectors 677 and 687 which render their output into flood illumination. Reflectors 677 and 687 may themselves be made from “cold mirror” materials, i.e., they may also be designed to transmit IR and reflect UV radiation.

Radiation emanating directly from lamps 679 and 689 as well as that reflected from reflectors 677 and 687 is further incident upon a set of reflectors 681. These reflectors are also cold mirrors designed to reflect only those UV wavelengths that are desired as described above. All other radiation including visible and most particularly the IR is transmitted by this set of cold mirrors. Therefore the substrate may be radiated only by those wavelengths that cause the desired effect on the film. The specific angle, distance, and orientation of the cold mirror reflectors 681 with respect to the lamps 679 and 689 may be optimized to maximize the UV intensity incident on the substrate and to optimize the uniformity of its illumination.

The chamber 671 is capable of holding a vacuum and/or containing gases at pressures above atmospheric pressure. For simplicity, only one station of one chamber 671 is shown. It is noted that in some embodiments, chamber 671 is one chamber in a multi-chambered apparatus, although chamber 671 could alternatively be part of a stand-alone single chambered apparatus. In either case, the chamber(s) may have one or more than one station. In some embodiments of the present invention, the UV process modules have one station. Suitable apparatus for implementation of the invention may include configurations as described herein of NOVA, Sequel, Vector and SOLA systems from Lam Research, Inc. of Fremont, Calif., and Endura, Centura, Producer and Nanocure systems from Applied Materials of Santa Clara, Calif.

Note that the UV light source configuration of FIG. 6 is only an example of a suitable configuration. In general, the lamp(s) are arranged to provide uniform UV radiation to the substrate. For example, other suitable lamp arrangements can include arrays of circular lamps concentrically or otherwise arranged, or lamps of smaller length arranged at 90 degree and 180 degree angles with respect to each other may be used. The light source(s) can be fixed or movable so as to provide light in appropriate locations on the substrate. Alternatively, an optical system, including for example a series of movable lenses, filters, and/or mirrors, can be controlled to direct light from different sources to the substrate at different times.

The UV light intensity can be directly controlled by the type of light source and by the power applied to the light source or array of light sources. Factors influencing the intensity of applied power include, for example, the number or light sources (e.g., in an array of light sources) and the light source types (e.g., lamp type or laser type). Other methods of controlling the UV light intensity on the substrate sample include using filters that can block portions of light from reaching the substrate sample. As with the direction of light, the intensity of light at the substrate can be modulated using various optical components such as mirrors, lenses, diffusers and filters. The spectral distribution of individual sources can be controlled by the choice of sources (e.g., mercury vapor lamp vs. xenon lamp vs. deuterium lamp vs. excimer laser, etc.) as well as the use of filters that tailor the spectral distribution. In addition, the spectral distributions of some lamps can be tuned by doping the gas mixture in the lamp with particular dopants such as iron, gallium, etc.

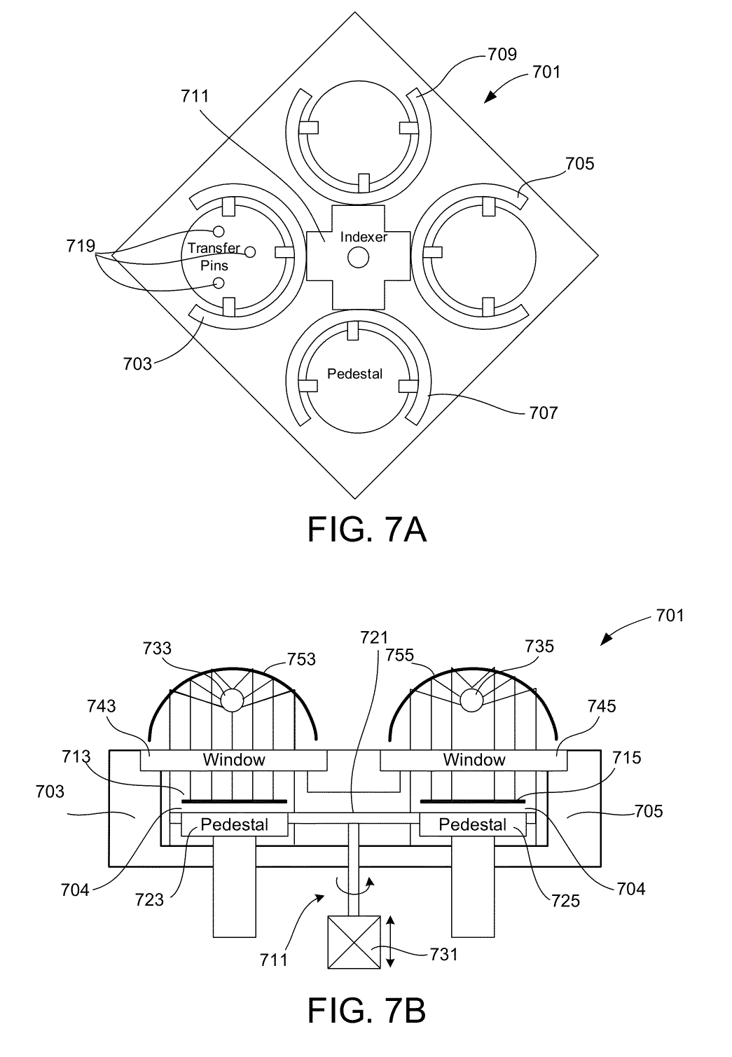

FIGS. 7A and 7B show one embodiment of an apparatus appropriate for use with certain embodiments of the invention that uses broadband UV sources. Chamber 701 includes multiple cure stations 703, 705, 707 and 709, each of which accommodates a substrate. Station 703 includes transfer pins 719. FIG. 7B is a side view of the chamber showing stations 703 and 705 and substrates 713 and 715 located above pedestals 723 and 725. There are gaps 704 between the substrates and the pedestals. The substrate may be supported above the pedestal by an attachment, such as a pin, or floated on gas. Parabolic or planar cold mirrors 753 and 755 are located above broadband UV source sets 733 and 735. UV light from lamp sets 733 and 735 passes through windows 743 and 745. Substrates 703 and 705 are then exposed to the radiation. In alternative embodiments, the substrate may be supported by the pedestals 723 and 725. In such embodiments, the lamps may or may not be equipped with cold mirrors. By making full contact with the pedestal, the substrate temperature may be maintained by use of a conductive gas such as helium or a mixture of helium and argon at a sufficient pressure for conductive heat transfer, typically between 20 and 760 Torr, but preferably between 100 and 600 Torr.

In operation, a substrate enters the chamber at station 703 where the first UV cure operation is performed. Subsequent UV cure operations may be performed, either in the same station or at a different station in various embodiments. Staged UV curing can help optimize the different processes (e.g., porogen removal and crosslinking) that occur during a cure process. For instance, a first stage of curing may be optimized to promote porogen removal and a second stage of curing may be optimized to promote crosslinking. In general, longer wavelengths are intended to drive porogen removal and shorter wavelengths are intended to drive crosslinking. While staged curing is beneficial in some embodiments, it is not always used. In certain cases, the UV cure operation is completed without changing the wavelengths and/or intensity/UV power applied to the substrate.

Returning to the embodiment of FIGS. 7A and 7B, pedestal temperature at station 703 is set to a first temperature, e.g. 400° C., with the UV lamps above station 703 set to a first intensity, e.g., 100% maximum intensity, and first wavelength range, e.g., about 185-800 nm. A flow of carbon dioxide or other weak oxidizer is flowed into the chamber and interacts with the substrate at station 703. Where carbon dioxide is present in the reaction chamber to promote porogen removal, the first wavelength range may include relatively low wavelengths for photodissociating carbon dioxide (e.g., wavelengths between about 185-230 nm). The first wavelength range may also include higher wavelengths (e.g., between about 305-800 nm in some cases) for optimized porogen removal. The optimal wavelength or range of wavelengths for porogen removal depends on the identity of the porogen. The first wavelength range may be continuous or discontinuous within the stated ranges. In some embodiments, the first wavelength range may have an intensity peak that corresponds with a wavelength or range of wavelengths that are optimized for direct removal of a particular porogen, with a much smaller intensity of radiation in the range of wavelengths that photodissociate carbon dioxide (the wavelengths for photodissociating carbon dioxide indirectly removing porogens via the photodissociated carbon dioxide fragments).

After curing in station 703 for a sufficient time such that absorption at the wavelength range is reduced, the substrate is transferred to station 705 for further curing at the same wavelength range or (in certain embodiments) at a shorter wavelength range. This second range of wavelengths may be optimized for crosslinking the matrix. In some cases the second range of wavelengths is between about 185-800 nm, or between about 295-800 nm. In some cases the second range of wavelengths includes wavelengths below about 250 nm (e.g., either including or excluding wavelengths above 250 nm). In these or other cases, the second range of wavelengths may exclude wavelengths that photodissociate carbon dioxide at the relevant temperature, as discussed further herein. Pedestal temperature at station 705 is set to a second temperature, which may or may not be the same as the first station and UV intensity is set to a second intensity, e.g. 90% intensity. A flow of carbon dioxide or other weak oxidizer may or may not interact with the substrate at station 705. Stations 707 and 709 may also be used for UV curing, and may have the same or different range of wavelengths as stations 703 and 705. In one embodiment, a substrate is exposed to UV radiation having intensity peaks at decreasing wavelengths as the substrate passes through the various stations.

In order to irradiate the substrate at different wavelengths or wavelengths ranges while using a broadband UV source, which generates radiation in a broad spectrum, optical components may be used in the radiation source to modulate the part of the broad spectrum that reaches the substrate. For example, reflectors, filters, or combination of both reflectors and filters may be used to subtract a part of the spectrum from the radiation. On reaching the filter, light may be reflected, absorbed into the filter material, or transmitted through.

Long pass filters are interference filters, which provide a sharp cut-off below a particular wavelength. They are useful for isolating specific regions of the spectrum. Long pass filters are used to pass, or transmit, a range of wavelengths and to block, or reflect, other wavelengths on the shorter wavelength side of the passband. Long wavelength radiation is transmitted, while short wavelength radiation is reflected. The region of high transmittance is known as the passband and the region of high reflectance is known as the reject or reflectance band. The roll-off region separates the pass-band and reflect-band. The complexity of long pass filters depends primarily upon the steepness of the transition region and also on the ripple specifications in the passband. In the case of a relatively high angle of incidence, polarization dependent loss may occur. Long pass filters are constructed of hard, durable surface materials covered dielectric coatings. They are designed to withstand normal cleaning and handling.

Another type of filter is UV cut-off filter. These filters do not allow UV transmission below a set value, e.g. 280 nm. These filters work by absorbing wavelengths below the cut-off value. This may be helpful to optimize the desired cure effect.

Yet another optical filter that may be used to select a wavelength range is a bandpass filter. Optical bandpass filters are designed to transmit a specific waveband. They are composed of many thin layers of dielectric materials, which have differing refractive indices to produce constructive and destructive interference in the transmitted light. In this way optical bandpass filters can be designed to transmit a specific waveband only. The range limitations are usually dependent upon the interference filters lens, and the composition of the thin-film filter material. Incident light is passed through two coated reflecting surfaces. The distance between the reflective coatings determines which wavelengths will destructively interfere and which wavelengths will be allowed to pass through the coated surfaces. In situations where the reflected beams are in phase, the light will pass through the two reflective surfaces. However, if the wavelengths are out of phase, destructive interference will block most of the reflections, allowing almost nothing to transmit through. In this way, interference filters are able to attenuate the intensity of transmitted light at wavelengths that are higher or lower than the desired range.

Another filter that can attenuate the wavelengths of the radiation reaching the substrate is the window 743, typically made of quartz. By changing the level of metal impurities and water content, the quartz window can be made to block radiations of undesired wavelengths. High-purity Silica Quartz with very little metal impurity is more transparent deeper into the ultraviolet. As an example, quartz with a thickness of 1 cm will have a transmittance of about 50% at a wavelength of 170 nm, which drops to only a few percent at 160 nm. Increasing levels of impurities in the quartz cause transmission of UV at lower wavelengths to be reduced. Electrically fused quartz has a greater presence of metallic impurities, limiting its UV transmittance wavelength to around 200 nm and longer. Synthetic silica, on the other hand, has much greater purity and will transfer down to 170 nm. For infrared radiation, the transmittance through quartz is determined by the water content. More water in the quartz means that infrared radiation is more likely absorbed. The water content in the quartz may be controlled through the manufacturing process. Thus, the spectrum of radiation transmission through the quartz window may be controlled to cutoff or reduce UV transmission at shorter wavelengths and/or to reduce infrared transmission at longer wavelengths.

In addition to changing the wavelengths by altering the radiation that reaches the substrate, radiation wavelength can also be controlled by modifying the properties of the light generator. Broadband UV source can generate a broad spectrum of radiation, from UV to infrared, but other light generators may be used to emit a smaller spectrum or to increase the intensity of a narrower spectrum. Other light generators may be mercury-vapor lamps, doped mercury-vapor lamps, electrode lamps, excimer lamps, excimer lasers, pulsed Xenon lamps, doped Xenon lamps. Lasers such as excimer lasers can emit radiation of a single wavelength. When dopants are added to mercury-vapor and to Xenon lamps, radiation in a narrow wavelength band may be made more intense. Common dopants are iron, nickel, cobalt, tin, zinc, indium, gallium, thallium, antimony, bismuth, or combinations of these. For example, mercury vapor lamps doped with indium emits strongly in the visible spectrum and around 450 nm; iron, at 360 nm; and gallium, at 320 nm. Radiation wavelengths can also be controlled by changing the fill pressure of the lamps. For example, high-pressure mercury vapor lamps can be made to emit wavelengths of 250 to 440 nm, particularly 310 to 350 nm more intensely. Low-pressure mercury vapor lamps emit at shorter wavelengths.

In addition to changing light generator properties and the use of filters, reflectors that preferentially deliver one or more segments of the lamps spectral output may be used. A common reflector is a cold mirror that allows infrared radiation to pass but reflects other light. Other reflectors that preferentially reflect light of a spectral band may be used. Therefore a substrate may be exposed to radiation of different wavelengths at different stations. Of course, the radiation wavelengths may be the same in some stations.

In FIG. 7B, pedestals 723 and 725 are stationary. Indexer 711 lifts and moves each substrate from one pedestal to another between each exposure period. Indexer 711 includes an indexer plate 721 attached to a motion mechanism 731 that has rotational and axial motion. Upward axial motion is imparted to indexer plate 721 to pick up substrates from each pedestal. The rotational motion serves to advance the substrates from one station to another. The motion mechanism then imparts downward axial motion to the plate to put the substrates down on the stations.

Pedestals 723 and 725 are electrically heated and maintained at a desired process temperature. Pedestals 723 and 725 may also be equipped with cooling lines to enable precise substrate temperature control. In an alternate embodiment, a large heater block may be used to support the substrates instead of individual pedestals. A thermally conductive gas, such as helium, is used to effect good thermal coupling between the pedestal and the substrate. In some embodiments, cast pedestals with coaxial heat exchangers may be used. These are described in above-referenced U.S. patent application Ser. No. 11/184,101.

FIGS. 7A and 7B show only an example of a suitable apparatus and other apparatuses designed for other methods involved in previous and/or subsequent processes may be used. For example, in another embodiment that uses broadband UV source, the substrate support is a carousel. Unlike with the stationary pedestal substrate supports, the substrates do not move relative to the carousel. After a substrate is loaded onto the carousel, the carousel rotates, if necessary, to expose the substrate to light from a UV lamp set. The carousel is stationary during the exposure period. After the exposure period, the carousel rotates to advance each substrate for exposure to the next set of lamps. Heating and cooling elements may be embedded within the rotating carousel. Alternatively the carousel may be in contact with a heater plate or hold the substrates so that they are suspended above a heater plate.

In certain embodiments, the substrates are exposed to UV radiation from focused, rather than, flood lamps. Unlike the broadband source embodiments wherein the substrates are stationary during exposure (as in FIGS. 7A and B), there is relative movement between the substrates and the light sources during exposure to the focused lights as the substrates are scanned. In other embodiments, the substrates may be rotated relative to the light sources to average out any differences in intensity across the substrate.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, lamp settings, wavelength settings, radio frequency (RF) generator settings, RF matching circuit settings, frequency settings, flow rate settings, fluid delivery settings, positional and operation settings, wafer transfers within a multi-station tool, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or treatment of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, a reactive and/or non-reactive UV thermal processing chamber, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed.

The subject matter of the present disclosure includes all novel and nonobvious combinations and sub-combinations of the various processes, systems and configurations, and other features, functions, acts, and/or properties disclosed herein, as well as any and all equivalents thereof.

What is claimed is:

1. A method of preparing a film on a substrate, the method comprising:
receiving the substrate in a processing chamber, the substrate having the film thereon, wherein the film comprises a carbon-containing dielectric film comprising porogens and a structure former, the film having a first dielectric constant;
flowing a processing gas into the reaction chamber and exposing the substrate to the flow of processing gas, wherein the processing gas comprises carbon dioxide and an inert carrier gas;
exposing the substrate and the processing gas to ultraviolet (UV) radiation, wherein the UV radiation comprises wavelengths that result in photodissociation of a portion of the carbon dioxide in the processing gas to thereby form carbon monoxide and oxygen radicals; and
reacting the film on the substrate with the oxygen radicals to thereby remove the porogens from the film, thereby reducing the dielectric constant of the film to a second dielectric constant.

2. The method of claim 1, wherein the UV radiation comprises wavelengths between about 185-230 nm.

3. The method of claim 2, wherein the UV radiation comprises wavelengths between about 190-210 nm.

4. The method of claim 1, wherein a partial pressure of carbon dioxide in the reaction chamber is between about 0.1-10 T.

5. The method of claim 4, wherein the partial pressure of carbon dioxide in the reaction chamber is between about 1-2 T.

6. The method of claim 1, wherein the processing gas comprises between about 5-30% carbon dioxide, as measured by volumetric flow rates.

7. The method of claim 6, wherein the processing gas comprises between about 10-25% carbon dioxide, as measured by volumetric flow rates.

8. The method of claim 1, wherein the second dielectric constant is between about 2.2-2.25.

9. The method of claim 1, wherein the processing gas does not comprise molecular oxygen (O₂).

10. The method of claim 9, wherein the processing gas does not comprise any of the following species: nitrogen dioxide (NO₂), nitric oxide (NO), ozone (O₃), and hydrogen peroxide (H₂O₂).

11. The method of claim 1, wherein exposing the substrate and the processing gas to UV radiation comprises performing a staged curing operation, wherein UV conditions exposed to the substrate during a first stage are different from UV conditions exposed to the substrate during a second stage.

12. The method of claim 1, wherein the reaction chamber comprises multiple stations for simultaneously processing multiple substrates.

13. The method of claim 12, wherein the reaction chamber comprises at least a first UV radiation source and a second UV radiation source, the first UV radiation source providing UV radiation to a first station and the second UV radiation source providing UV radiation to a second station, the method further comprising modulating at least one of the first and second UV radiation sources to independently modulate the photodissociation of carbon dioxide in the first and second stations.

14. The method of claim 13, wherein modulating at least one of the first and second UV radiation sources comprises changing a range of wavelengths exposed to the substrate from at least one of the first and second UV radiation sources.

15. The method of claim 12, wherein the reaction chamber comprises at least a first UV radiation source for providing UV radiation to a first station and a second UV radiation source for providing UV radiation to a second station, wherein the first UV radiation source exposes the substrate to radiation at wavelengths that photodissociate carbon dioxide, and wherein the second UV radiation source exposes the substrate to radiation at wavelengths that do not substantially photodissociate carbon dioxide.

16. The method of claim 1, wherein the film has a thickness of about 200 nm or less.

17. The method of claim 1, wherein the photodissociation of carbon dioxide preferentially occurs proximate the substrate as compared to locations in the reaction chamber removed from the substrate.

18. The method of claim 17, wherein during exposing the substrate and processing gas to UV radiation, there is a temperature differential of at least about 150° C. between the substrate and a window through which the UV radiation passes before reaching the substrate.

19. A method comprising:
receiving a substrate in a processing chamber, the substrate having a film thereon, wherein the film comprises porogens and a structure former; and
exposing the substrate to a processing gas while exposing the substrate to ultraviolet (UV) radiation to thereby remove the porogen, wherein the processing gas comprises an inert carrier gas and between about 5-30% carbon dioxide, as measured by volumetric flow rate.

20. The method of claim 19, wherein the UV radiation comprises wavelengths between about 185-230 nm.

21. The method of claim 19, wherein the processing gas is substantially free of molecular oxygen.

22. An apparatus for preparing low-k dielectric films, the apparatus comprising:
a reaction chamber;
a substrate support for supporting a substrate in the reaction chamber;
an ultraviolet (UV) radiation source configured to deliver UV radiation to the substrate on the substrate support;
an inlet for providing processing gas to the reaction chamber and an outlet for removing material from the reaction chamber; and
a controller comprising instructions for exposing the substrate to the processing gas while exposing the substrate to UV radiation from the UV radiation source to thereby remove porogens from an exposed film on the substrate, wherein the processing gas comprises an inert carrier gas and between about 5-30% carbon dioxide, as measured by volumetric flow rate.
